(19) United States
(12) Patent Application Publication
(10) Pub. No.: US 2026/0182061 A1
(43) Pub. Date: Jun. 25, 2026

(54) HIGH DYNAMIC RANGE IMAGE SENSOR FOR REDUCING LOSS OF INFRARED SENSITIVITY RATIO

(71) Applicant: Pixelplus Co.,Ltd., Seongnam-si (KR)

(72) Inventors: Ji Min LEE, Seongnam-si (KR); Youn Sub LEE, Suwon-si (KR)

(21) Appl. No.: 19/420,739

(22) Filed: Dec. 16, 2025

(30) Foreign Application Priority Data
Dec. 23, 2024 (KR) 10-2024-0194788
May 12, 2025 (KR) 10-2025-0060999

(51) Int. Cl. H10F 39/00; H04N 25/20; H04N 25/585

(52) U.S. Cl. CPC H10F 39/8063; H04N 25/20; H04N 25/585

(57) ABSTRACT

Provided is a high dynamic range (HDR) image sensor for reducing a loss of infrared sensitivity ratio is disclosed. The HDR image sensor includes: a low-sensitivity pixel formed on a P-type substrate; high-sensitivity pixels formed on both sides adjacent to the low-sensitivity pixel. The low-sensitivity pixel is configured such that a higher hole-density neutral region is formed beneath a photodiode of the low-sensitivity pixel. According to the HDR image sensor for reducing a loss of infrared sensitivity ratio, forming an additional P+ implant region beneath a photodiode of the low-sensitivity pixel reduces the inflow of crosstalk (X-talk) electrons from the high-sensitivity pixel into the low-sensitivity pixel, thereby improving infrared HDR characteristics.

### CROSS-REFERENCE TO RELATED APPLICATION

This application claims priority to and the benefit of Korean Patent Application Nos. 10-2024-0194788 filed on December 23, 2024, and 10-2025-0060999 filed on May 12, 2025, the disclosures of which are incorporated herein by reference in their entirety.

### BACKGROUND

### TECHNICAL FIELD

The present disclosure relates to a high dynamic range (HDR) image sensor, and more specifically, to an HDR image sensor for reducing a loss of infrared sensitivity ratio.

### Description of Related Technology

High Dynamic Range (HDR) images require collecting a wide range of optical information in order to accurately represent various brightness levels. To this end, the spatially varying exposure (SVE) method is used, which implements an HDR image by setting different exposure levels for respective pixels within a pixel array.

However, in the conventional SVE method, all pixels have the same light-receiving structure, and sensitivity differences between pixels are artificially induced through an attenuation structure. The attenuation structure is implemented by adjusting an aperture shielding ratio using a metal layer, or by laminating materials having different transparency or transmittance on the pixels. However, this structure increase crosstalk (X-talk) between pixels, resulting in a significant reduction in sensitivity ratio, particularly in the infrared (IR) region.

IR light has a long wavelength, which penetrates deep into a pixel structure and affects adjacent pixels. This causes crosstalk (X-talk) from high-sensitivity pixels to low-sensitivity pixels, degrading the signal accuracy of the low-sensitivity pixels.

In particular, the crosstalk (X-talk) reduces the sensitivity ratio difference intended in the SVE method, thereby degrading the quality of HDR images. Existing solutions include forming a full-depth deep trench isolation (FDTI) structure to prevent crosstalk (X-talk), but this approach has drawbacks such as increased process complexity and cost, and reduced sensitivity due to a decrease in the pixel light-receiving area.

FIG. 1 is an exemplary diagram of a conventional pixel array structure for implementing the SVE method. FIG. 2 is an exemplary diagram of an HDR sensor output graph obtained by synthesizing signal outputs according to respective exposure levels. FIG. 3 is a diagram illustrating a conventional pixel structure in which multiple materials having different light attenuation characteristics are applied to form sensitivity differences between pixels.

Hereinafter, a more detailed explanation is provided with reference to FIGS. 1 to 3.

First, referring to FIG. 1, the SVE technology is configured to implement high dynamic range (HDR) characteristics by inducing exposure differences for the respective four pixels on the Bayer pattern. This method enables the acquisition of multiple images having four different sensitivity levels because the SVE method is applied to the Bayer pattern.

Referring to FIG. 2, the multiple images acquired as above are synthesized to generate an HDR image. In the SVE method, exposure differences between pixels may be induced by adjusting exposure times for respective pixels, by shielding different aperture regions with a metal layer, or by laminating layers having different transparency or transmittance on the respective pixels.

As an example, FIG. 3 shows a method of laminating material layers having different transmittances on the respective pixels. To secure different transmittance characteristics, materials having different light attenuation characteristics are laminated on respective pixels of the pixel array of the Bayer Pattern. In this case, because ATL layers formed of different materials with different light attenuation rates are laminated on the respective pixels, sensitivity differences occur in resulting images depending on the light attenuation characteristics of the laminated ATL layers.

That is, this configuration causes differences in exposure levels for the respective pixels within the Bayer pattern, and an HDR image is generated by synthesizing images having different sensitivities.

However, the pixel structure according to the conventional SVE method is vulnerable to crosstalk (X-talk) caused by IR light with a large penetration depth. IR components and crosstalk leaking from adjacent pixels have a significant impact on the signal variation of low-sensitivity pixels, which significantly limits the sensitivity ratio characteristics between pixels that the SVE method aims to secure.

Therefore, it is difficult to implement infrared HDR characteristics in the conventional SVE method.

### [Related Art Document]

### [Patent Document]

Korean Patent Registration No. 10-1768857

Korean Patent Registration No. 10-1972748

### SUMMARY

The present disclosure provides a high dynamic range (HDR) image sensor for reducing a loss of infrared sensitivity ratio.

In one general aspect of the present disclosure, a high dynamic range (HDR) image sensor for reducing a loss of infrared sensitivity ratio includes: a low-sensitivity pixel; high-sensitivity pixels formed on both sides adjacent to the low-sensitivity pixel; and micro lenses formed on respective regions corresponding to the low sensitivity pixel and the high sensitivity pixels.

The HDR image sensor may further include a P+ type pixel separation implant formed by doping side surfaces of the low-sensitivity pixel and the high-sensitivity pixel.

The low-sensitivity pixel may include a PD_N layer; and a P-type substrate formed on the PD_N layer.

The high-sensitivity pixel may include a PD_N layer; and a P-type substrate formed on the PD_N layer.

### BRIEF DESCRIPTION OF THE DRAWINGS

FIG. 1 is an exemplary diagram illustrating a conventional pixel array structure for implementing the spatially varying exposure (SVE) method.

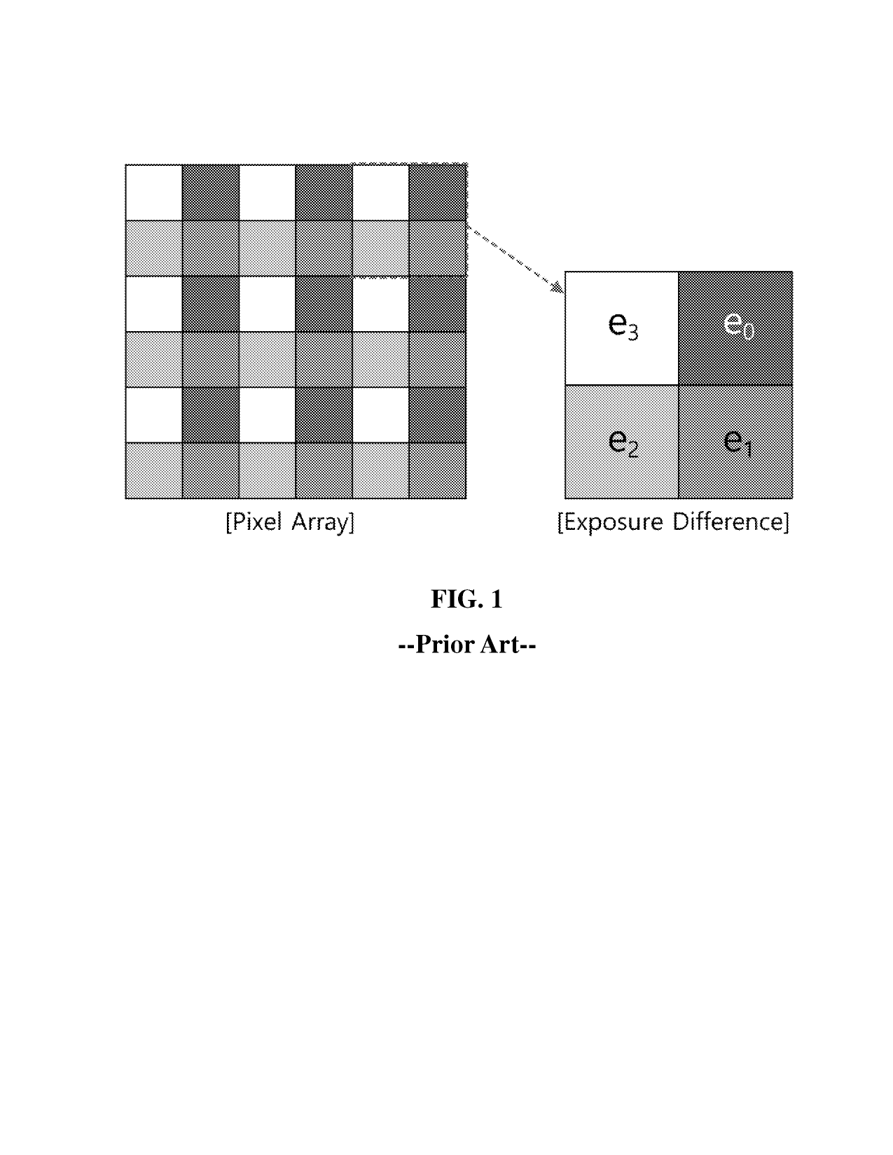

FIG. 2 is an exemplary diagram illustrating an high dynamic range (HDR) sensor output graph obtained by synthesizing signal outputs according to exposure levels.

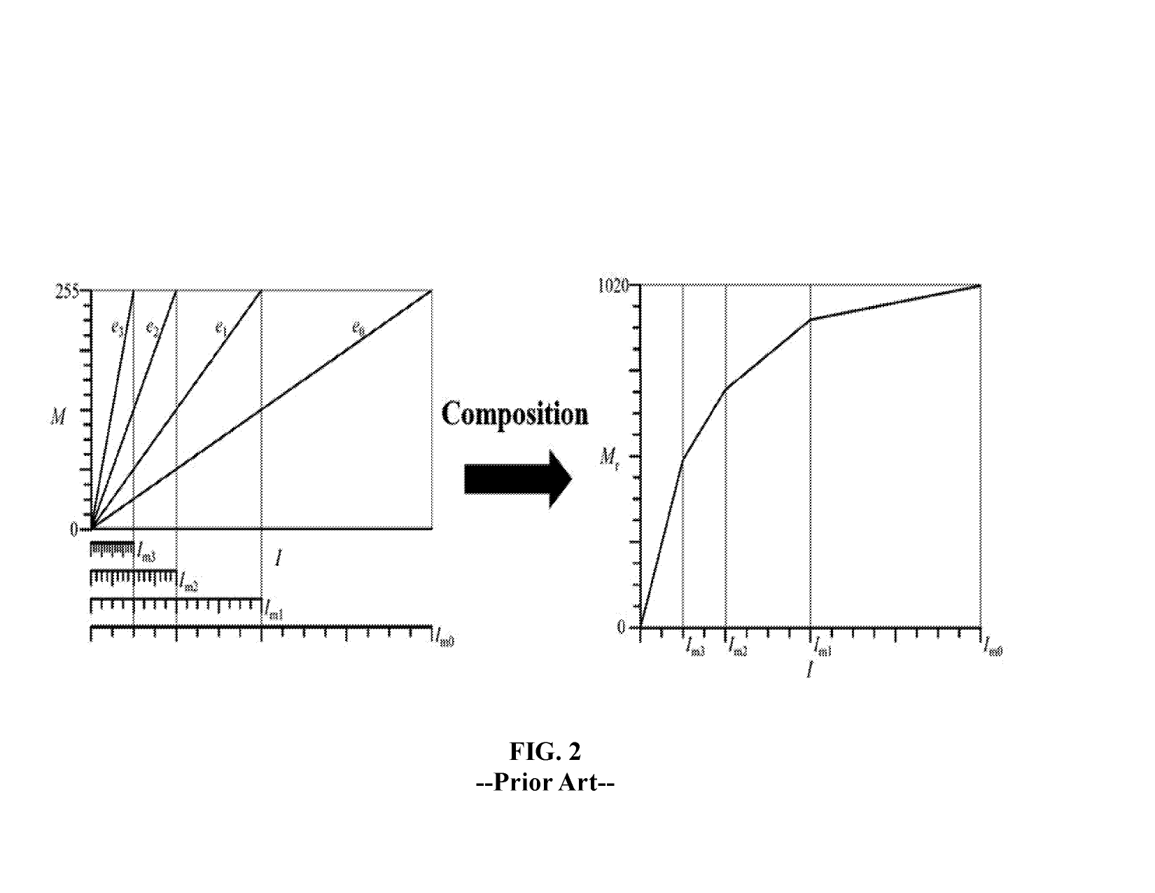

FIG. 3 is a diagram illustrating a conventional pixel structure in which multiple materials having different light attenuation characteristics are applied to form sensitivity differences between pixels.

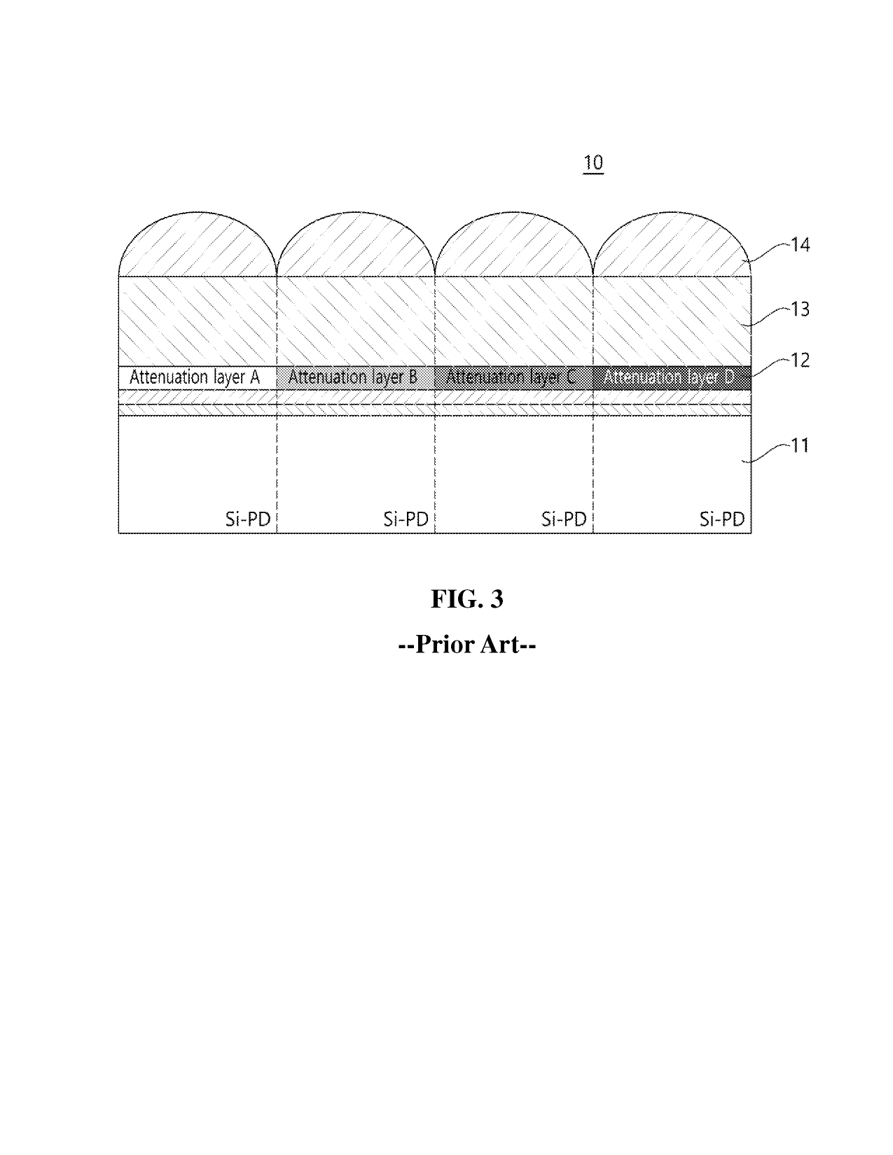

FIG. 4 is a cross-sectional side view of an HDR image sensor for reducing a loss of infrared sensitivity ratio according to one embodiment of the present disclosure.

FIGS. 5A-5B are diagrams illustrating differences in electric-field and electron-inflow characteristics depending on whether Additional P+ Chain Implant (APCI) is applied, according to one embodiment of the present disclosure.

FIGS. 6A-6D are diagrams illustrating an SVE-based pixel application structure for reducing crosstalk (X-talk) and increasing infrared sensitivity, according to one embodiment of the present disclosure.

### DETAILED DESCRIPTION

The present disclosure may be modified in various ways and may have various embodiments. Specific embodiments are illustrated in the drawings and will be described in detail to enable those skilled in the art to practice the present disclosure. However, this is not intended to limit the present disclosure to specific embodiments, and it should be understood that all modifications, equivalents, and substitutes falling within the spirit and scope of the present disclosure are included. In the drawings, like reference numerals are used to designate like components.

Terms such as first, second, A, B, and the like may be used to describe various components, but the components should not be limited by such terms. These terms are used only to distinguish one component from another. For example, without departing from the scope of the present disclosure, a first component may be referred to as a second component, and similarly, a second component may be referred to as a first component. The term “and/or” includes any combination of a plurality of related described items, or any one of the plurality of related described items.

When a component is said to be “connected” or “coupled” to another component, it should be understood that it may be directly connected or coupled to the other component, or one or more additional components may be interposed therebetween. On the other hand, when a component is said to be “directly connected” or “directly coupled” to another component, it should be understood that no other components are present therebetween.

The terminology used in this application is for the purpose of describing particular embodiments only and is not intended to limit the present disclosure. Singular expressions should be understood to include plural expressions unless the context clearly indicates otherwise. In this application, terms such as “include” or “have” are intended to specify the presence of a feature, integer, step, operation, component, part, or combination thereof, but should not be interpreted as precluding the possibility of the presence or addition of one or more other features, integers, steps, operations, components, parts, or combinations thereof.

Unless otherwise defined, all terms used herein, including technical or scientific terms, have the same meaning as commonly understood by one of ordinary skill in the art to which the present disclosure pertains. Terms defined in commonly used dictionaries should be interpreted to be consistent with their meanings in the context of the relevant technical field, and should not be interpreted in an overly idealized or excessively formal sense unless explicitly defined herein.

Hereinafter, embodiments according to the present disclosure will be described in detail with reference to the accompanying drawings.

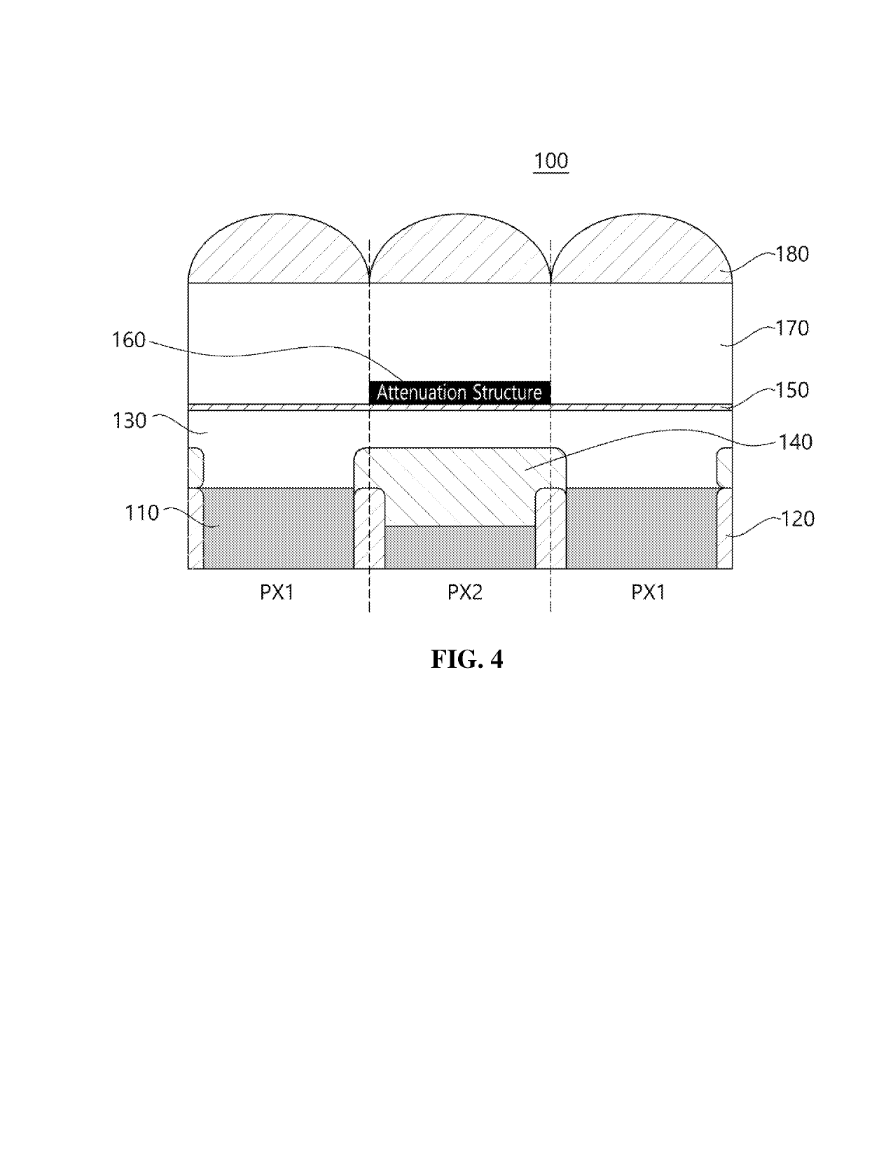

FIG. 4 is a cross-sectional side view of an HDR image sensor for reducing a loss of infrared sensitivity ratio according to one embodiment of the present disclosure.

Referring to FIG. 4, a high dynamic range (HDR) image sensor 100 for reducing a loss of infrared sensitivity ratio according to an embodiment of the present disclosure may be configured to include a low-sensitivity pixel PX2, high-sensitivity pixels PX1 formed on both adjacent sides of the low-sensitivity pixel PX2, a PD_N layer 110, a P+ type pixel separation implant 120, a P-type substrate 130, an Additional P+ Chain Implant (APCI) 140, an anti-reflection layer 150, a light attenuation layer 160, a planarization layer 170, and micro lenses 180.

Hereinafter, a detailed configuration is described.

The high-sensitivity pixels PX1 may be formed on both adjacent sides of the low-sensitivity pixel PX2, and the P+ type pixel separation implant 120 may be formed by doping to separate pixel regions.

Here, the low-sensitivity pixel PX2 may include the PD_N layer 110, the P-type substrate 130, and the APCI 140.

The P-type substrate 130 may be provided on the PD_N layer 110.

The APCI 140 may be formed by implanting into a lower portion of the PD_N layer 110.

The high-sensitivity pixels PX1 may include the PD_N layer 110 and the P-type substrate 130.

The P-type substrate 130 may be provided on the PD_N layer 110.

The P+ type pixel separation implant 120 may be formed by doping in a PD_N layer of each of the low-sensitivity pixel PX2 and the high-sensitivity pixel PX1 to separate pixel regions.

The APCI 140 may be formed by implanting impurities into a lower portion of the PD_N layer 110 of the low-sensitivity pixel PX2.

When using a conventional pixel process, the pixel structure of the conventional spatially varying exposure (SVE) method causes a significant loss of infrared high dynamic range (HDR) sensitivity ratio due to crosstalk (X-talk) components. In order to mitigate the loss, the APCI 140 implements a method of forming different depletion region structures between the high-sensitivity pixels PX1 and the low-sensitivity pixel PX2.

By adding the structure of the APCI 140 to the low-sensitivity pixel structure, a structure for controlling the influence of infrared crosstalk (X-talk) flowing from the high-sensitivity pixel PX1 may be configured.

The APCI 140 additionally formed in the low-sensitivity pixel structure forms a higher hole density neutral region beneath the photodiode and, within this region, artificially induces diffusion and recombination of electrons generated by infrared crosstalk (X-talk) flowing from the high-sensitivity pixel PX1, thereby reducing the number of electrons drifting toward the photodiode of the low-sensitivity pixel PX2.

In addition, an electric field of the high-sensitivity pixels PX1 extends to a low P-concentration region of the low-sensitivity pixel PX2, thereby inducing some electrons of the crosstalk (X-talk) component that have entered the low-sensitivity pixel PX2 to drift toward the high-sensitivity pixels PX1. Using this method, an infrared HDR image with minimal loss of sensitivity ratio characteristics between the high-sensitivity pixels PX1 and the low-sensitivity pixel PX2 may be implemented.

The anti-reflection layer 150 may be formed on the P-type substrate 130 of the low-sensitivity pixel PX2 and the high-sensitivity pixels PX1.

The anti-reflection layer 150 formed on the high-sensitivity pixels PX1 may be configured with a scattering pattern to secure infrared sensitivity ratio characteristics of the high-sensitivity pixels PX1.

The scattering pattern may be composed of a plurality of protruding structures that extend downward.

Meanwhile, the light attenuation layer 160 may be formed on the anti-reflection layer 150 of the low-sensitivity pixel PX2 and may be configured to reduce the sensitivity of the low-sensitivity pixel PX2 to which the APCI 140 is applied.

The planarization layer 170 may be formed on the low-sensitivity pixel PX2 and the high-sensitivity pixels PX1.

The micro lenses 180 may be formed on respective regions corresponding to the low-sensitivity pixel PX2 and the high-sensitivity pixels PX1 on the planarization layer 170.

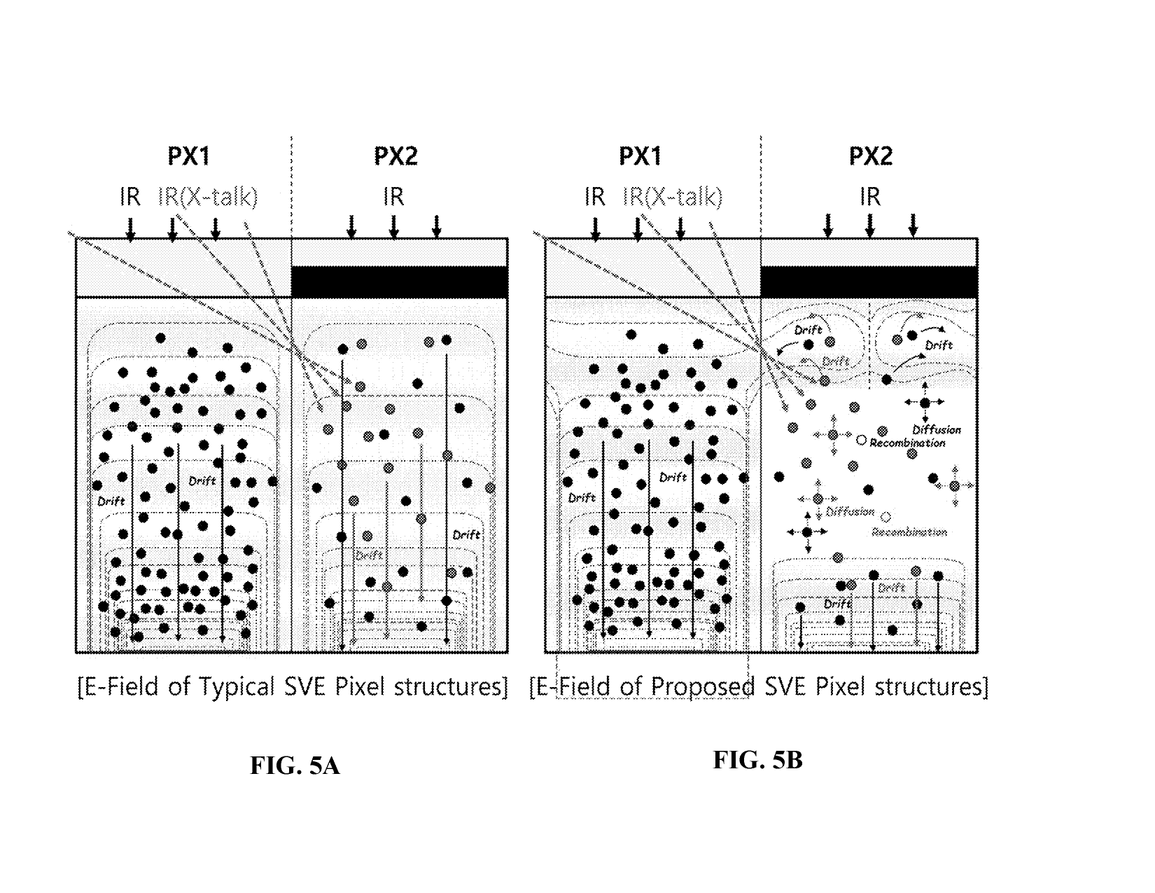

FIGS. 5A-5B are diagrams illustrating differences in electric-field and electron-inflow characteristics depending on whether Additional P+ Chain Implant (APCI) is applied, according to one embodiment of the present disclosure.

First, for the purpose of explaining the example in FIGS. 5A-5B, it is assumed that infrared (IR) light at a predetermined angle are incident only on the high-sensitivity pixel PX1. FIG. 5A shows an electric-field tendency for two pixels used in the conventional SVE method. Since the implant structures of the pixels used in a typical SVE method are identical, the same electric field may be formed across the entire substrate. When infrared light is incident on the high-sensitivity pixel PX1, a main infrared component generated in the high-sensitivity pixel PX1 drifts and is collected in the high-sensitivity pixel PX1. However, a parasitic infrared component penetrating from the high-sensitivity pixel PX1 into the low-sensitivity pixel PX2 is generated in the region of the low-sensitivity pixel PX2 and is collected therein as a crosstalk (X-talk) component. In general, the crosstalk (X-talk) component is amplified in wavelength regions with deep penetration depth. Since the high-sensitivity pixel PX1 has high-sensitivity characteristics, a relatively large number of crosstalk (X-talk) electrons that may flow toward adjacent pixels are generated. When the crosstalk (X-talk) electrons penetrate into the low-sensitivity pixel PX2, the penetration has a significant impact on the loss of infrared sensitivity ratio.

FIG. 5B illustrates a difference in electric-field characteristics between two pixels when the APCI structure proposed in the present disclosure is applied to the low-sensitivity pixel PX2. Since the high-sensitivity pixel PX1 has the same structure as the pixel used in the conventional SVE method, an electric field is formed over the entire substrate region. On the other hand, in the low-sensitivity pixel PX2 to which the APCI structure is applied, a high P+ doping region is formed beneath the photodiode, resulting in a reduction of the electric field region for the photodiode of the low-sensitivity pixel PX2. That is, the region of the APCI structure forms a high hole-density neutral region beneath the photodiode of the low-sensitivity pixel PX2 without a loss at the saturation level, and induces electrons that have penetrated from the high-sensitivity pixel PX1 into the high hole-density neutral region to diffuse or recombine within the low-sensitivity pixel PX2, thereby preventing drift collection of crosstalk (X-talk) signals entering the photodiode of the low-sensitivity pixel PX2.

In addition, the electric field of the high-sensitivity pixel PX1 extends to a portion of the substrate of an adjacent low-sensitivity pixel PX2, thereby inducing some electrons of the crosstalk (X-talk) component that have entered the low-sensitivity pixel PX2 to drift back to the high-sensitivity pixel PX1 and be collected. Through this phenomenon, the structure proposed in the present disclosure significantly reduces the influence of crosstalk (X-talk) flowing from the high-sensitivity pixel PX1 into the low-sensitivity pixel PX2.

In this case, there also exists an influence of crosstalk (X-talk) from the low-sensitivity pixel PX2 to the high-sensitivity pixel PX1 due to infrared incident light on the low-sensitivity pixel PX2. However, due to the sensitivity difference between pixels in the SVE method, the amount of infrared light incident on the low-sensitivity pixel PX2 is greatly reduced through the attenuation structure, resulting in a very small influence on the high-sensitivity pixel PX1. For example, when a sensitivity ratio between two pixels is 10:1, and assuming that 100 photons of the same intensity infrared light are incident on the entire area of the high-sensitivity pixel PX1, the number of photons flowing into the entire area of the low-sensitivity pixel PX2 may be 10. Assuming that the crosstalk (X-talk) ratio is 20% for each of these incident photons, 20 electrons that may represent crosstalk (X-talk) elements are present in the high-sensitivity pixel PX1, and 2 electrons that may represent crosstalk (X-talk) elements are present in the low-sensitivity pixel PX2.

If the above assumption is applied to FIG. 5A, which illustrates a typical SVE-based pixel structure, the total number of signal electrons in the high-sensitivity pixel PX1 is calculated as 82 by summing 80 signal electrons in the photodiode and two crosstalk (X-talk) electrons flowing from the low-sensitivity pixel PX2. Similarly,, the total number of signal electrons in the low-sensitivity pixel PX2 increases significantly to 28 by combining 8 signal electrons in the photodiode and 20 crosstalk (X-talk) electrons flowing from the high-sensitivity pixel PX1. When the calculated number of electrons for each pixel is converted into a sensitivity ratio, the ratio becomes approximately 3:1, showing that the crosstalk (X-talk) component flowing from the high-sensitivity pixel PX1 to the low-sensitivity pixel PX2 dominantly contributes to the reduction in sensitivity ratio.

Next, as shown in FIG. 5B, when the low-sensitivity pixel PX2 to which the APCI structure proposed in the present disclosure is applied is used, the sensitivity ratio is calculated under the same conditions, and the effect may be confirmed as follows.

The effect of the proposed APCI structure is that it converts a large portion of the electric field region of the low-sensitivity pixel PX2 into a high-hole-concentration neutral region, in which crosstalk electrons flowing from the high-sensitivity pixel PX1 are prevented from drifting to the low-sensitivity pixel PX2 and are instead guided into diffusion or recombination. The diffuse electrons induced in this manner do not have specific directionality, and the probability that these electrons are collected by the low-sensitivity pixel PX2 is less than about 25%.

In addition, since the electric field of the high-sensitivity pixel PX1 extends to a portion of the adjacent low-sensitivity pixel PX2, some electrons of the crosstalk (X-talk) component that have entered the low-sensitivity pixel PX2 are induced to drift back to the high-sensitivity pixel PX1 and be collected.

Accordingly, in the structure of the present disclosure, assuming that the area ratio among a partial substrate region, an APCI neutral region, and a photodiode depletion region of the low-sensitivity pixel PX2 is 1:2:1, the total number of signal electrons of the high-sensitivity pixel PX1 is calculated as 87 by summing 80 signal electrons in the photodiode and 7 crosstalk (X-talk) electrons flowing from the low-sensitivity pixel PX2 (i.e., the sum of electrons drifting back to the high-sensitivity pixel PX1 and electrons re-diffused to the high-sensitivity pixel PX1).

Similarly, the total number of signal electrons in the low-sensitivity pixel PX2 is calculated as approximately 9.5 by summing approximately 2 signal electrons within the reduced photodiode depletion region, 5 crosstalk (X-talk) electrons directly introduced from the 20 crosstalk (X-talk) electrons flowing from the high-sensitivity pixel PX1, and approximately 2.5 electrons collected in the low-sensitivity pixel PX2 by diffusion.

Converting the numbers back to a sensitivity ratio yields a sensitivity ratio of approximately 9:1, and it may be seen that the proposed structure suppresses the decrease in sensitivity ratio. In this way, the APCI structure reduces the infrared crosstalk (X-talk) when using the typical SVE method, minimizes the significant loss of infrared sensitivity characteristics, and enables securing infrared HDR characteristics.

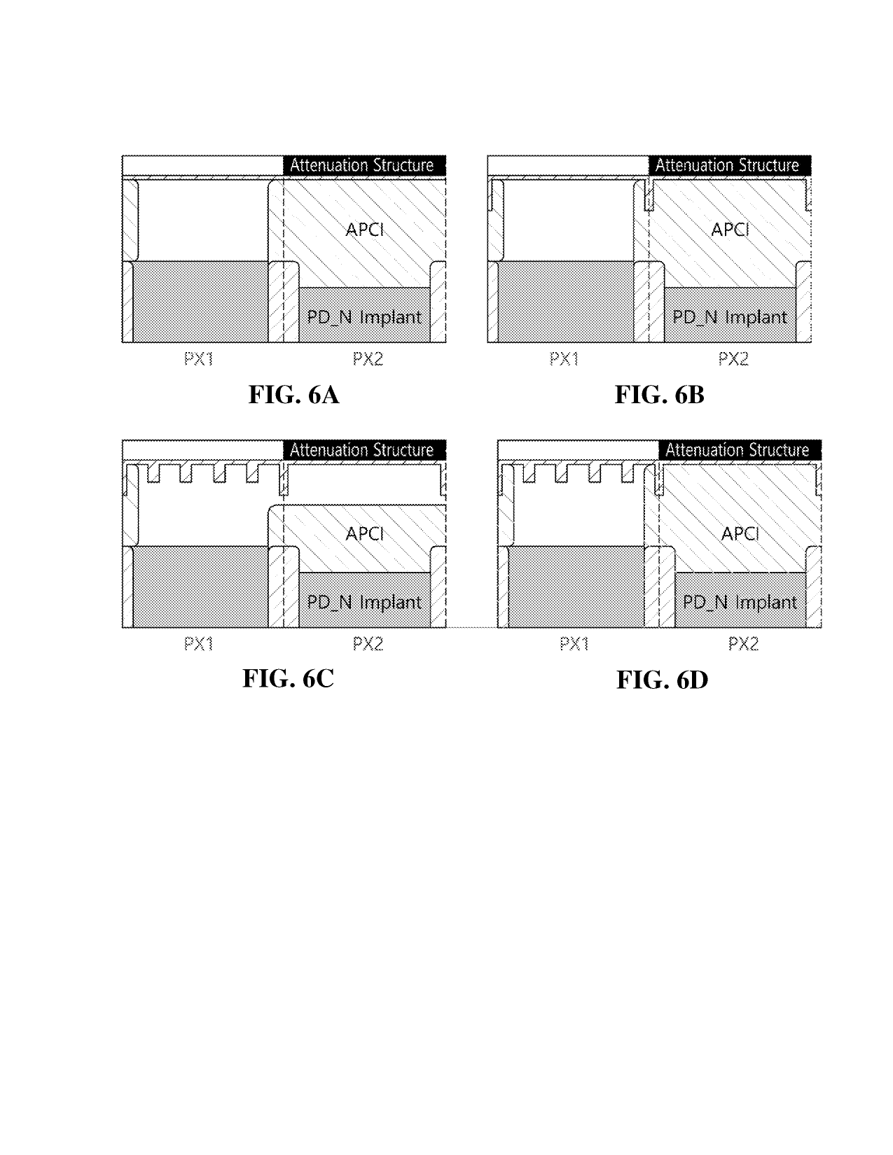

FIGS. 6A-6D are diagrams illustrating an SVE-based pixel application structure for reducing crosstalk (X-talk) and increasing infrared sensitivity, according to one embodiment of the present disclosure.

Referring to FIGS. 6A-6D, the high-sensitivity pixel PX1, i.e., a crosstalk (X-talk) component of the high-sensitivity pixel PX1, may be controlled by applying an APCI structure to the entire lower region of the photodiode as shown in FIG. 6A, and the APCI structure may also be added to a pixel based on a back-side deep trench isolation (BDTI) structure as shown in FIG. 6B.

In addition, in order to secure a higher sensitivity ratio by increasing the infrared sensitivity of the high-sensitivity pixel PX1, a scattering-pattern structure may be added to the high-sensitivity pixel structure as shown in of FIGS. 6C-6D.

This scattering-pattern structure may be modified and applied in various structures to suit the design purpose.

According to the HDR image sensor for reducing a loss of infrared sensitivity ratio, forming an additional P+ implant region beneath a photodiode of the low-sensitivity pixel reduces the inflow of crosstalk (X-talk) electrons from the high-sensitivity pixel into the low-sensitivity pixel, thereby improving infrared HDR characteristics.

Although the present disclosure has been described with reference to the embodiments above, it will be understood by those skilled in the art that various modifications and changes may be made without departing from the spirit and scope of the present disclosure as defined in the claims below.

1. A high dynamic range (HDR) image sensor for reducing a loss of infrared sensitivity ratio, comprising:
a low-sensitivity pixel;
high-sensitivity pixels formed on both sides adjacent to the low-sensitivity pixel; and
micro lenses formed on respective regions corresponding to the low sensitivity pixel and the high sensitivity pixels.

2. The HDR image sensor of claim 1, further comprising a P+ type pixel separation implant formed by doping on both side surfaces of the low-sensitivity pixel and the high-sensitivity pixel.

3. The HDR image sensor of claim 2, wherein the low-sensitivity pixel comprises
a PD_N layer; and
a P-type substrate formed on the PD_N layer.

4. The HDR image sensor of claim 3, wherein the high-sensitivity pixel comprises:
a PD_N layer; and
a P-type substrate formed on the PD_N layer.
